(19) United States
(12) Patent Application Publication
(10) Pub. No.: US 2026/0180499 A1
(43) Pub. Date: Jun. 25, 2026

(54) SOLAR POWER GENERATION MODULE AND ITS PREPARATION METHOD, AND PREPARATION METHOD FOR PEROVSKITE DEVICE

(71) Applicant: GUANGDONG BILIGHT INTELLIGENT MANUFACTURING TECHNOLOGY CO., LTD., Dongguan (CN)

(72) Inventors: Wei-Chia FANG, Dongguan (CN); Chung-Chin HSIAO, Dongguan (CN); Tzu-Chien WEI, Dongguan (CN)

(21) Appl. No.: 19/367,941

(22) Filed: Oct. 24, 2025

(30) Foreign Application Priority Data
Dec. 24, 2024 (CN) 202411919433.7

(51) Int. Cl. H02S 30/10; H10K 39/10; H10K 71/50

(52) U.S. Cl. CPC H02S 30/10; H10K 39/10; H10K 71/50

(57) ABSTRACT

A solar power generation module and its preparation method, as well as a preparation method for a perovskite device. The preparation method for the solar power generation module includes steps of: forming multiple perovskite devices on the substrate, where each perovskite device includes a light absorption region and a functional region, the light absorption region is configured to convert solar energy into electrical energy, and the functional region includes a bus electrode electrically connected to the light absorption region to collect the electrical energy; laminating a cover plate onto a surface of each perovskite device; and cutting the substrate and cover plate to obtain multiple solar power generation modules. The solar power generation module includes a sub-substrate, a perovskite device, and a sub-cover plate, which are sequentially stacked in layer. The sub-substrate is obtained by cutting the substrate, and the sub-cover plate is obtained by cutting the cover plate.

### CROSS-REFERENCE TO RELATED APPLICATION

Pursuant to 35 U.S.C. § 119 and the Paris Convention, this application claims the benefit of Chinese Patent Application No. 202411919433.7 filed on Dec. 24, 2024, the content of which is incorporated herein by reference.

### FIELD OF TECHNOLOGY

The following relates to the field of solar cell technology, more particularly to solar power generation module and its preparation method, as well as a preparation method for a perovskite device.

### BACKGROUND

The statements provided herein are merely background information related to the present application, and do not necessarily constitute any prior arts. Currently, traditional solar photovoltaic modules are primarily designed for outdoor environmental applications. When exposed to sunlight outdoors, the photovoltaic modules absorb light and convert it into electricity. The generated electricity is then transmitted through attached busbars, which connect the positive and negative lines to the junction box. The junction box is oversized and requires a reserved frame area for placement, resulting in an excessively large overall size for the solar photovoltaic module. Thus, it is unsuitable for applications in small-area indoor solar photovoltaics or polygonal solar photovoltaic component designs.

### SUMMARY

It is an objective of the present application to provide a solar power generation module and its preparation method, as well as a preparation method for a perovskite device, aiming to address the issue of excessive overall size in traditional solar photovoltaic modules.

In accordance with a first aspect of embodiments of the present application, a preparation method for a solar power generation module is provided, which includes steps of: providing a substrate; forming multiple perovskite devices on the substrate, where each of the perovskite devices includes a light absorption region and a functional region, the light absorption region is configured to convert solar energy into electrical energy, and the functional region includes a bus electrode electrically connected to the light absorption region to collect the electrical energy; laminating a cover plate onto a surface of each of the perovskite devices; and cutting the substrate and the cover plate to obtain multiple solar power generation modules; each of the solar power generation modules includes a sub-substrate, a perovskite device, and a sub-cover plate sequentially stacked in layer; the sub-substrate is obtained by cutting the substrate, and the sub-cover plate is obtained by cutting the cover plate.

In one embodiment, the functional region also includes a positioning structure located on the substrate, the positioning structure is configured to position each of the perovskite devices when cutting the substrate and the cover plate.

In accordance with a second aspect of embodiments of the present application, preparation method for a perovskite device is provided, which is applied to prepare the perovskite device as described above and includes steps of: forming a first electrode layer and a second electrode layer on a substrate, where the first electrode layer includes a first bus-electrode layer and a second bus-electrode layer located in a functional region and sequentially arranged at an interval along a first direction, and a first light-absorption electrode layer, multiple second light-absorption electrode layers and a third light-absorption electrode layer located in a light absorption region and sequentially arranged at intervals along the first direction, the first light-absorption electrode layer is connected to the first bus-electrode layer, and the third light-absorption electrode layer is connected to the second bus-electrode layer, the second electrode layer is located in the functional region, and the first direction is parallel to the substrate; forming multiple light absorption units that sequentially arranged at intervals along the first direction on the first light-absorption electrode layer, the second light-absorption electrode layers and the third light-absorption electrode layer, where one light absorption unit is in contact with a surface of each of two adjacent light-absorption electrode layers away from the substrate; the light absorption unit includes a first sidewall and a second sidewall opposite to each other along a first direction, as well as a third sidewall and a fourth sidewall opposite to each other along a second direction; the second direction is parallel to the substrate and perpendicular to the first direction; the light absorption region and the functional region are sequentially arranged along the second direction; forming a third electrode layer on a surface of the first bus-electrode layer facing away from the substrate; forming multiple fourth electrode layers and multiple fifth electrode layers on the surface of each light absorption unit, where the first bus-electrode layer, the second bus-electrode layer, and the third electrode layer constitute a bus electrode. Each light absorption unit corresponds to one fourth electrode layer and one fifth electrode layer. The fourth electrode layer is located on a side of a corresponding light absorption unit facing away from the substrate. The fifth electrode layer covers the first sidewall or the fourth sidewall of the corresponding light absorption unit. The fourth electrode layer is connected to the second light-absorption electrode layer or the third electrode layer via a corresponding fifth electrode layer.

In one embodiment, the step of forming the first electrode layer and the second electrode layer on the substrate includes: forming a first material layer on the substrate; and pattern-etching the first material layer to obtain the first electrode layer and the second electrode layer.

In one embodiment, the light absorption unit includes a first transmission layer, perovskite light absorption layer, and a second transmission layer sequentially stacked in layer in a direction away from the substrate, and the first transmission layer is also in contact with the substrate to fill gaps among the light-absorption electrode layers.

In one embodiment, a surface of the second electrode layer facing away from the substrate is provided with the first transmission layer, the perovskite light absorption layer, and the second transmission layer sequentially stacked in layer. The second electrode layer along with the first transmission layer, the perovskite light absorption layer, and the second transmission layer on the second electrode layer constitute the positioning structure.

In one embodiment, the step of forming the multiple light absorption units sequentially arranged at intervals along the first direction on the first light-absorption electrode layer, the second light-absorption electrode layers, and the third light-absorption electrode layer includes: sequentially forming a second material layer, a third material layer, and a fourth material layer on the substrate, a surface of the first electrode layer facing away from the substrate, and the second electrode layer; and sequentially pattern-etching the fourth material layer, the third material layer, and the second material layer to form the multiple light absorption units and the positioning structure.

In one embodiment, the bus electrode also includes a sixth electrode layer located on a surface of the second bus-electrode layer facing away from the substrate, and the positioning structure also includes a seventh electrode layer located on a surface of the second transmission layer facing away from the substrate.

In one embodiment, the step of forming the third electrode layer on the surface of the first bus-electrode layer facing away from the substrate, and the step of forming the multiple fourth and fifth electrode layers on the surface of each light absorption unit, include: forming a fifth material layer covering the light absorption region and the functional region; and pattern-etching the fifth material layer to obtain the third, fourth, fifth, sixth, and seventh electrode layers.

In accordance with a third aspect of embodiments of the present application, a solar power generation module is provided, which includes: a sub-substrate, a perovskite device, and a sub-cover, sequentially stacked in layer. The perovskite device includes a light absorption region and a functional region. The light absorption region is configured to convert solar energy into electrical energy. The functional region includes a bus electrode electrically connected to the light absorption region to collect the electrical energy.

Embodiments of the present application offer distinct advantages over prior arts: the cutting method enables further miniaturization of solar power generation modules without being constrained by raw material dimensions. Since the perovskite devices in the solar power generation modules each has a busbar, an external circuit can be directly connected to these busbars, eliminating the need for a junction box and reducing the overall size of the solar power generation module.

### BRIEF DESCRIPTION OF THE DRAWINGS

FIG. 1 is a flow chart of a preparation method for a solar power generation module according to an embodiment of the present application;

FIG. 2 is a schematic diagram of an arrangement of perovskite devices according to an embodiment of the present application;

FIG. 3 is a schematic cross-sectional view of a solar power generation module according to an embodiment of the present application;

FIG. 4 is a flow chart of a preparation method for a perovskite device according to an embodiment of the present application;

FIG. 5 is a schematic diagram of a first electrode layer and a second electrode layer according to an embodiment of the present application;

FIG. 6 is a top view of a device after performing step S120 according to an embodiment of the present application;

FIG. 7 is a cross-sectional view taken along line A-A of FIG. 6;

FIG. 8 is a top view of a device after performing step S130 according to an embodiment of the present application;

FIG. 9 is a cross-sectional view taken along line B-B of FIG. 8;

FIG. 10 is a cross-sectional view taken along line C-C of FIG. 8; and

FIG. 11 is a cross-sectional view taken along line D-D of FIG. 8.

### DETAILED DESCRIPTION OF THE EMBODIMENTS

To illustrate the technical problems to be solved, technical solutions, and beneficial effects of the present application more clearly, the present application is further described in detail below with reference to the accompanying drawings and embodiments. It should be understood that specific embodiments described herein are merely illustrative of the present application and are not intended to limit the present application.

It should be noted that when an element is referred to as being “fixed to” or “disposed on” another element, it may be directly or indirectly on the other element. When an element is referred to as being “connected to” another element, it may be directly or indirectly connected to the other element.

It should be understood that terms such as “length,” “width,” “upper,” “lower,” “front,” “back,” “left,” “right,” “vertical,” “horizontal,” “top,” “bottom,” “inner,” and “outer” to indicate positions or location relationships are based on the positions or location relationships shown in the drawings and are intended solely to facilitate the description of the present application and simplify the description. These terms do not indicate or imply that a device or element referred to must have a specific orientation, be formed, or operate in a specific orientation, and thus should not be construed as limiting the present application.

In addition, the terms “first” and “second” are used for descriptive purposes only and should not be construed as indicating or implying relative importance or implicitly specifying the quantity of the indicated technical features. Thus, features defined with “first” or “second” may explicitly or implicitly include one or more such features. In the description of the present application, the term “multiple” means two or more, unless explicitly and specifically defined otherwise.

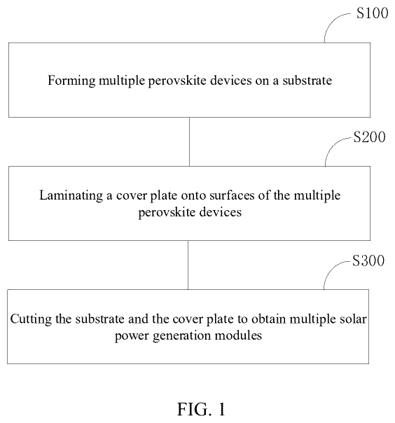

FIG. 1 shows a flow chart of a preparation method for a solar power generation module according to a first embodiment of the present application. For ease of illustration, only the portions relevant to this embodiment are shown. The details are as follows:

A preparation method for a solar power generation module includes steps S100 to S300.

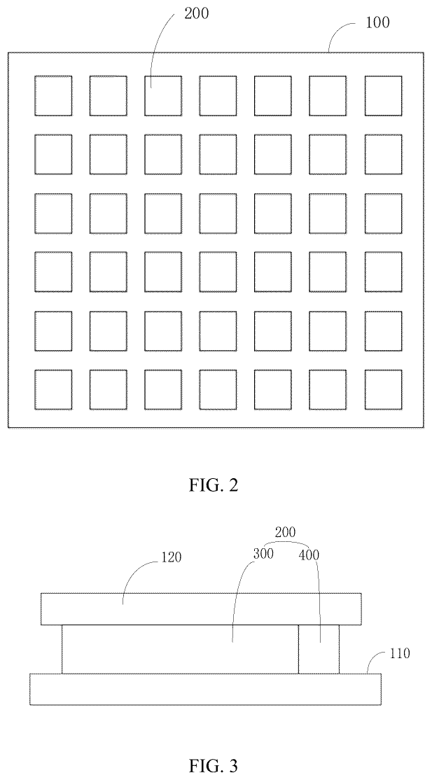

In step S100: multiple perovskite devices are formed on a substrate. As shown in FIGS. 2 and 3, the perovskite device 200 includes a light absorption region 300 and a functional region 400. The light absorption region 300 is used to convert solar energy into electrical energy. The functional region 400 includes a bus electrode. The bus electrode is electrically connected to the light absorption region 300 to collect the electrical energy.

By directly providing the bus electrode on the perovskite device 200, the need for busbars and a corresponding junction box is eliminated, miniaturizing the device.

In step S200: a cover plate is laminated onto a surface of each perovskite device.

Specifically, the cover plate may be bonded to a side of each perovskite device 200 facing away from the substrate 100 using an encapsulating material.

In step S300: the substrate and cover plate are cut to produce multiple solar power generation modules. As shown in FIG. 3, the solar power generation module includes a sub-substrate 110, a perovskite device 200, and a sub-cover plate 120 sequentially stacked in layer. The sub-substrate 110 is obtained by cutting the substrate 100, and the sub-cover plate 120 is obtained by cutting the cover plate.

By cutting, the size of the solar power generation module can be further reduced without being limited by the size of the raw materials.

Since each perovskite device 200 in the solar power generation module has a bus electrode, the external circuit can be directly connected to the bus electrode, eliminating the need for a junction box and reducing the overall size of the solar power generation module.

In one embodiment, as shown in FIG. 3, the functional region 400 also includes a positioning structure located on the substrate 100. The positioning structure is configured to position each perovskite device 200 when the cover plate is laminated onto the surface of each perovskite device, and/or when measuring a bonding tolerance of the cover plate after being laminated, and/or when cutting the substrate 100 and the cover plate, and/or when connecting the bus electrode to an external circuit, so as to improve product yield and reduce the complexity of the production process.

The shape of the positioning structure may be customized according to actual needs. In some embodiments, the orthographic projection of the positioning structure on the substrate 100 is a cross.

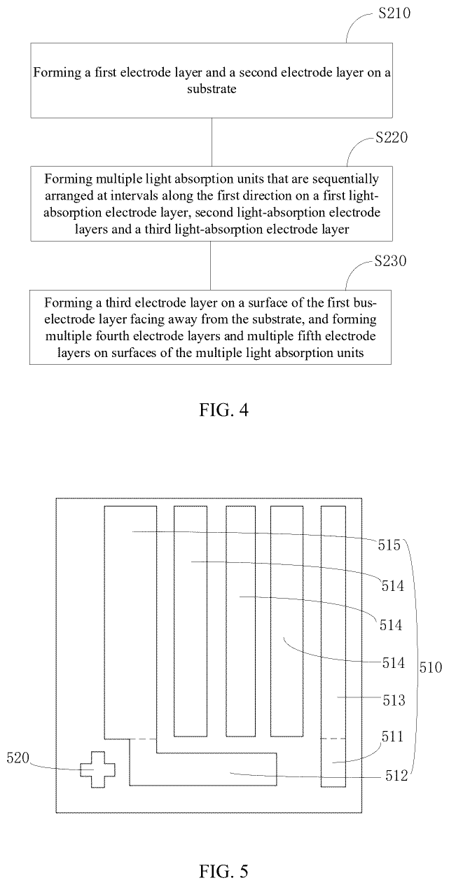

FIG. 4 shows a flow chart of a preparation method for a perovskite device according to the first embodiment of the present application. For ease of illustration, only the portions relevant to this embodiment are shown. The details are as follows:

A preparation method for a perovskite device 200, for preparing the perovskite device 200 according to any of the above embodiments, and the preparation method includes steps S110 to S130.

In step S110: a first electrode layer and a second electrode layer are formed on substrate, respectively.

As shown in FIG. 5, the first electrode layer 510 includes a first bus-electrode layer 511 and a second bus-electrode layer 512, sequentially arranged at an interval along a first direction, located in the functional region 400. The first electrode layer 510 also includes a first light-absorption electrode layer 513, multiple second light-absorption electrode layers 514, and a third light-absorption electrode layer 515, sequentially arranged at intervals along the first direction, located in the light absorption region 300. The first light-absorption electrode layer 513 is connected to the first bus-electrode layer 511, and the third light-absorption electrode layer 515 is connected to the second bus-electrode layer 512. The second electrode layers 520 are located in the functional region 400. The first direction is parallel to the substrate 100.

In step S120: multiple light absorption units are sequentially arranged at intervals along the first direction on the light-absorption electrode layers.

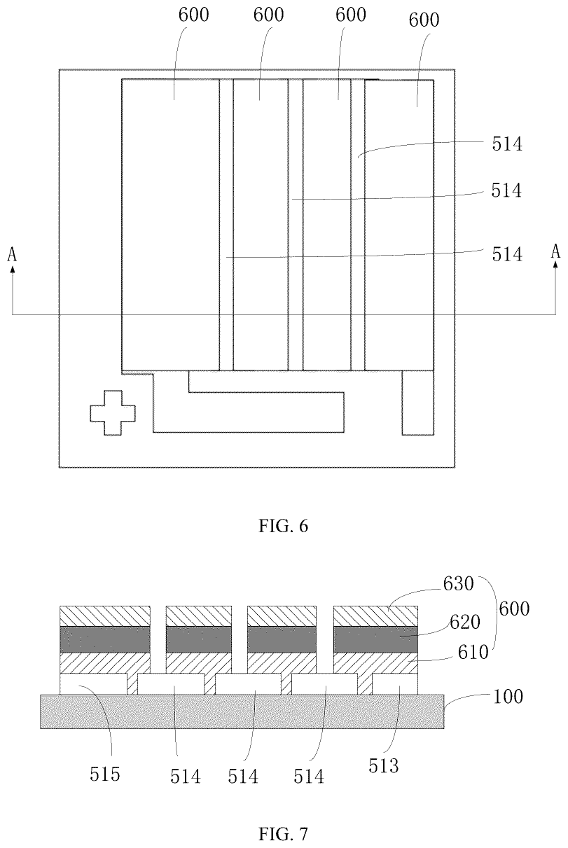

As shown in FIGS. 6 and 7, at least one light absorption unit 600 contacts a surface of each of two adjacent light-absorption electrode layers facing away from the substrate 100. The light absorption unit 600 includes a first sidewall and a second sidewall arranged opposite to each other along a first direction, and a third sidewall and a fourth sidewall arranged opposite to each other along a second direction. The second direction is parallel to the substrate 100 and perpendicular to the first direction. The light absorption region 300 and the functional region 400 are arranged in sequence along the second direction.

In some embodiments, at least one light absorption unit 600 is disposed between two adjacent light-absorption electrode layers on the side facing away from the substrate 100.

In step S130: forming a third electrode layer on a surface of the first bus-electrode layer facing away from the substrate, and forming multiple fourth electrode layers and multiple fifth electrode layers on surfaces of the multiple light absorption units.

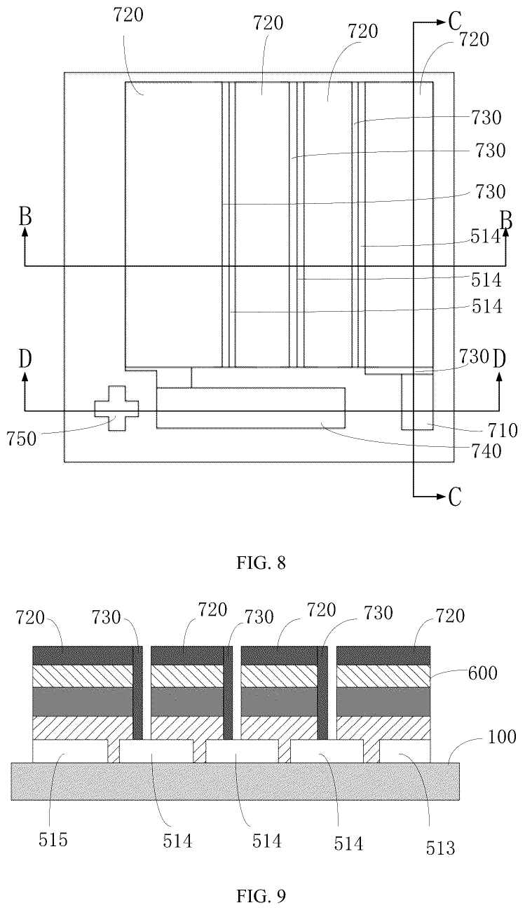

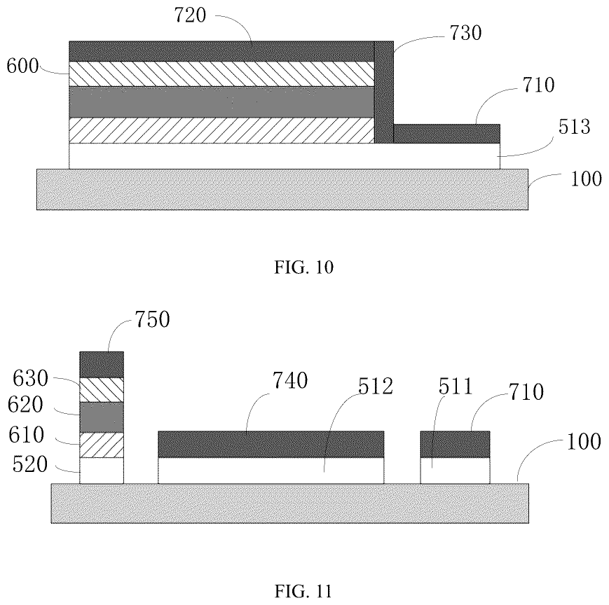

As shown in FIGS. 8, 9, 10, and 11, the first bus-electrode layer 511, the second bus-electrode layer 512, and the third electrode layer 710 constitute the bus electrode. Each light absorption unit 600 corresponds to one fourth electrode layer 720 and one fifth electrode layer 730. The fourth electrode layer 720 is located on a side of the corresponding light absorption unit 600 facing away from the substrate 100. The fifth electrode layer 730 covers the first sidewall or the fourth sidewall of the corresponding light absorption unit 600. The fourth electrode layer 720 is connected to the second light-absorption electrode layer 514 or the third electrode layer 710 via the corresponding fifth electrode layer 730.

It should be understood that the third electrode layer 710 may be used to connect to an external circuit. The fifth electrode layer 730 covering the first sidewall of the corresponding light absorption unit 600 may connect a corresponding fourth electrode layer 720 to the second light-absorption electrode layer 514. The fifth electrode layer 730 covering the fourth sidewall of a corresponding light absorption unit 600 may connect the corresponding fourth electrode layer 720 to the third electrode layer 710. The multiple fourth electrode layers 720 and multiple fifth electrode layers 730 may cooperate with the first light-absorption electrode layer 513, the multiple second light-absorption electrode layers 514, and the third light-absorption electrode layer 515 to sequentially connect the light absorption units 600 in series between the first bus-electrode layer 511 and the second bus-electrode layer 512.

In one embodiment, the step S110 includes steps S111 to S112.

In step S111: a first material layer is formed on the substrate.

The first material layer may be prepared by deposition. Specifically, the first material layer includes at least one of indium tin oxide (ITO), fluorine tin oxide (FTO), an IMI composite electrode, and aluminum zinc oxide (AZO).

In step S112: pattern etching is performed on the first material layer to form the first electrode layer and the second electrode layer.

It should be understood that after etching the first material layer, the unetched first material layer will form the first electrode layer 510 and the second electrode layer 520.

In one embodiment, as shown in FIG. 7, the light absorption unit 600 includes first transmission layer 610, a perovskite light absorption layer 620, and a second transmission layer 630 sequentially stacked in layer along a direction away from the substrate 100. The first transmission layer 610 also contacts the substrate 100 to fill gaps among the light-absorption electrode layers.

The perovskite light absorption layer 620 can convert received solar energy into electrical energy. The first transmission layer 610 and the second transmission layer 630 can effectively improve the photoelectric conversion efficiency and stability of the perovskite light absorption layer 620.

It should be noted that, in actual operation, one transmission layer is configured to transmit electrons, while the other transmission layer is used to transmit holes. For example, the first transmission layer 610 may be configured to transmit holes, while the second transmission layer 630 is configured to transmit electrons.

Since any two adjacent light-absorption electrode layers are spaced apart, a certain gap exists between the two adjacent light-absorption electrode layers. Thus, when forming the first transmission layer 610, the gap between the light-absorption electrode layers may be filled first.

In one embodiment, as shown in FIG. 11, the surface of the second electrode layer 520 facing away from the substrate 100 is provided with a first transmission layer 610, a perovskite light absorption layer 620, and a second transmission layer 630 sequentially stacked in layer. The second electrode layer 520, along with the first transmission layer 610, the perovskite light absorption layer 620 and the second transmission layer 630 formed on the second electrode layer, constitute a positioning structure.

It should be noted that, without adding additional process steps, the positioning structure can be formed on the second electrode layer 520 while forming the light absorption unit 600.

In one embodiment, step S120 includes steps S121 to S122.

In step S121: a second material layer, a third material layer, and a fourth material layer are sequentially formed on the substrate, the surface of the first electrode layer facing away from the substrate, and the second electrode layer.

Specifically, the second material layer, the third material layer, and the fourth material layer may be formed by deposition.

During the formation of the second material layer, the second material layer fills the gaps between the light-absorption electrode layers.

The second material layer and the fourth material layer may be made of at least one of zinc oxide (ZnO), tin oxide (SnO₂), antimony-doped tin oxide (Sb:SnO₂), tungsten oxide (WO₃), titanium oxide (TiO₂), nickel oxide (NiO), antimony tin oxide (ATO), PEDOT:PSS hydrogel, polytriarylamine (PTAA), Spiro, and Al-doped ZnO.

The third material layer includes at least one of an organic/inorganic lead halide perovskite and a lead-free perovskite.

In step S122: the fourth material layer, the third material layer, and the second material layer are pattern-etched in sequence, to form the multiple light absorption units and the positioning structure.

It will be appreciated that after pattern-etching the fourth material layer, the third material layer, and the second material layer, the remaining portions of the second material layer, the third material layer, and the fourth material layer will form multiple light absorption units 600 and the positioning structure.

In one embodiment, as shown in FIG. 11, the bus electrode also includes a sixth electrode layer 740 located on a surface of the second bus-electrode layer 512 facing away from the substrate 100, and the positioning structure also includes a seventh electrode layer 750 located on a surface of the second transmission layer 630 facing away from the substrate 100.

In one embodiment, step S130 includes steps S131 to S132.

In step S131: a fifth material layer is formed covering the light absorption region and the functional region.

The fifth material layer may be prepared by deposition. Specifically, the fifth material layer includes at least one of indium tin oxide (ITO), fluorine tin oxide (FTO), an IMI composite electrode, and aluminum zinc oxide (AZO).

In step S132: the fifth material layer is pattern-etched to form the third electrode layer, the fourth electrode layer, the fifth electrode layer, the sixth electrode layer, and the seventh electrode layer.

As shown in FIGS. 8, 9, 10, and 11, it can be understood that after etching the fifth material layer, the unetched portions of the fifth material layer will form the third electrode layer 710, the fourth electrode layer 720, the fifth electrode layer 730, the sixth electrode layer 740, and the seventh electrode layer 750.

FIG. 3 shows a schematic diagram of a solar power generation module provided by the first embodiment of the present application. For ease of illustration, only the portions relevant to this embodiment are shown. The details are as follows:

A solar power generation module includes: a sub-substrate 110, a perovskite device 200, and a sub-cover plate 120, sequentially stacked in layer. The perovskite device 200 includes a light absorption region 300 and a functional region 400. The light absorption region 300 is configured to convert solar energy into electrical energy. The functional region 400 includes a bus electrode electrically connected to the light absorption region 300 to collect the electrical energy.

Since the perovskite device 200 in each solar power generation module has a bus electrode, the external circuit can be directly connected to the bus electrode, eliminating the need for a junction box and reducing the overall size of the solar power generation module.

It should be understood that the sequence numbers of the steps in the above embodiments do not imply the order of execution, and the execution sequence of each process should be determined by its function and inherent logic and does not constitute any limitation on the implementation of the embodiments of the present application.

It will be clearly understood by persons skilled in the art that, for the sake of convenience and brevity, the above-mentioned division of functional units and modules is used only as an example. In actual applications, the above-mentioned functions may be assigned to different functional units or modules as needed. That is, the internal structure of the device may be divided into different functional units or modules to perform all or part of the functions described above. The functional units and modules in the embodiments may be integrated into a single processing unit, each unit may exist physically as a separate unit, or two or more units may be integrated into a single unit. These integrated units may be implemented as either hardware or software functional units. Furthermore, the specific names of the functional units and modules are for ease of distinction only and are not intended to limit the protection scope of the present application. For specific operating processes of the units and modules in the above-mentioned systems, references may be made to the corresponding processes in the aforementioned method embodiments which thus will not be elaborated upon here.

In the above-mentioned embodiments, the descriptions of each embodiment have their own specific focus. For portions not described or detailed in a particular embodiment, reference may be made to the relevant descriptions of other embodiments.

The above-mentioned embodiments are intended only to illustrate the technical solutions of the present application and are not intended to limit the present application. Although the present application has been described in detail with reference to the aforementioned embodiments, persons of ordinary skill in the art should understand that modifications may be made to the technical solutions described in the aforementioned embodiments, or that some of the technical features therein may be replaced with equivalents. Such modifications or replacements do not deviate from the spirit and scope of the technical solutions of the various embodiments of the present application and thus should all be included within the protection scope of the present application.

What is claimed is:

1. A preparation method for a solar power generation module, comprising:
forming multiple perovskite devices on a substrate, wherein each of the multiple perovskite devices comprises a light absorption region and a functional region, the light absorption region being configured to convert solar energy into electrical energy, and the functional region comprising a bus electrode electrically connected to the light absorption region, to collect the electrical energy;
laminating a cover plate onto surfaces of the multiple perovskite devices; and
cutting the substrate and the cover plate to obtain multiple solar power generation modules; each of the multiple solar power generation modules comprising a sub-substrate, a perovskite device, and a sub-cover plate, sequentially stacked in layer; the sub-substrate being obtained by cutting the substrate, and the sub-cover plate being obtained by cutting the cover plate.

2. The method according to claim 1, wherein the functional region further comprises a positioning structure located on the substrate, the positioning structure is configured to position each of the multiple perovskite devices.

3. A preparation method for a perovskite device, comprising:
forming a first electrode layer and a second electrode layer on a substrate;
wherein the first electrode layer comprises a first bus-electrode layer and a second bus-electrode layer located in a functional region and sequentially arranged at an interval along a first direction, and a first light-absorption electrode layer, multiple second light-absorption electrode layers and a third light-absorption electrode layer located in a light absorption region and sequentially arranged at intervals along the first direction; the first light-absorption electrode layer is connected to the first bus-electrode layer, and the third light-absorption electrode layer is connected to the second bus-electrode layer; the second electrode layer is configured for forming a positioning structure; the first direction is parallel to the substrate;
forming multiple light absorption units that are sequentially arranged at intervals along the first direction on the first light-absorption electrode layer, the multiple second light-absorption electrode layers and the third light-absorption electrode layer;
wherein at least one light absorption unit is in contact with a surface of each of two adjacent light-absorption electrode layers facing away from the substrate; each of the multiple light absorption units comprises a first sidewall and a second sidewall opposite to each other along the first direction, as well as a third sidewall and a fourth sidewall opposite to each other along a second direction, wherein the second direction is parallel to the substrate and perpendicular to the first direction; the light absorption region and the functional region are sequentially arranged along the second direction;
forming a third electrode layer on a surface of the first bus-electrode layer facing away from the substrate; the first bus-electrode layer, the second bus-electrode layer, and the third electrode layer constituting a bus electrode; and
forming multiple fourth electrode layers and multiple fifth electrode layers on surfaces of the multiple light absorption units;
wherein each light absorption unit corresponds to one fourth electrode layer and one fifth electrode layer, each fourth electrode layer is located on a side of a corresponding light absorption unit facing away from the substrate, each fifth electrode layer covers the first sidewall or the fourth sidewall of the corresponding light absorption unit, and each fourth electrode layer is connected to the second light-absorption electrode layer or the third electrode layer via a corresponding fifth electrode layer.

4. The preparation method according to claim 3, wherein the forming the first electrode layer and the second electrode layer on the substrate comprises:
forming a first material layer on the substrate; and
pattern-etching the first material layer to obtain the first electrode layer and the second electrode layer.

5. The preparation method according to claim 3, wherein each of the multiple light absorption units comprises a first transmission layer, a perovskite light absorption layer and a second transmission layer sequentially stacked in layer along a direction away from the substrate, wherein the first transmission layer is formed further in contact with the substrate to fill gaps among the first light-absorption electrode layer, the multiple second light-absorption electrode layers and the third light-absorption electrode layer.

6. The preparation method according to claim 5, wherein the first transmission layer, the perovskite light absorption layer, and the second transmission layer are sequentially stacked in layer on a surface of the second electrode layer facing away from the substrate, wherein the second electrode layer along with the first transmission layer, the perovskite light absorption layer, and the second transmission layer on the second electrode layer constitute the positioning structure.

7. The preparation method according to claim 6, wherein the forming the multiple light absorption units that are sequentially arranged at intervals along the first direction on the first light-absorption electrode layer, the multiple second light-absorption electrode layers, and the third light-absorption electrode layer comprises:
sequentially forming a second material layer, a third material layer, and a fourth material layer on the substrate, a surface of the first electrode layer facing away from the substrate, and the second electrode layer; and
sequentially pattern-etching the fourth material layer, the third material layer, and the second material layer to form the multiple light absorption units and the positioning structure.

8. The preparation method according to claim 6, wherein the bus electrode further comprises a sixth electrode layer located on a surface of the second bus-electrode layer facing away from the substrate, and the positioning structure further comprises a seventh electrode layer located on a surface of the second transmission layer facing away from the substrate.

9. The preparation method according to claim 8, wherein the forming the third electrode layer on the surface of the first bus-electrode layer facing away from the substrate and the forming the multiple fourth electrode layers and the multiple fifth electrode layers on the surfaces of the multiple light absorption units, comprise:
forming a fifth material layer covering the light absorption region and the functional region; and
pattern-etching the fifth material layer to obtain the third electrode layer, the fourth electrode layer, the fifth electrode layer, the sixth electrode layer, and the seventh electrode layer.

10. A solar power generation module, comprising: a sub-substrate, a perovskite device, and a sub-cover plate sequentially stacked in layer; wherein the perovskite device comprises a light absorption region and a functional region, the light absorption region is configured to convert solar energy into electrical energy, and the functional region comprises a bus electrode electrically connected to the light absorption region, to collect the electrical energy.
